(19) United States
(12) Patent Application Publication
(10) Pub. No.: US 2025/0273864 A1
(43) Pub. Date: Aug. 28, 2025

(54) Antenna Device and Antenna Device Assembly

(71) Applicant: Tyco Electronics Holdings (Bermuda) No. 7 Limited, Hamilton (BM)

(72) Inventors: Simon Tseng, Taipei (TW); Kuei Hsu Hsiang, Taipei (TW); Tsung Han Liu, Taipei (TW); Sin-Hooi Cheah, Prai (MY)

(73) Assignee: Tyco Electronics Holdings (Bermuda) No. 7 Limited, Hamilton (BM)

(21) Appl. No.: 19/062,164

(22) Filed: Feb. 25, 2025

(30) Foreign Application Priority Data
Feb. 27, 2024 (CN) 202410214247.7

(51) Int. Cl. H01Q 9/04; H01Q 1/38

(52) U.S. Cl. CPC H01Q 9/0414; H01Q 1/38

(57) ABSTRACT

An antenna device includes a substrate having a first main surface, a second main surface opposite the first main surface, and a side surface connecting the first main surface and the second main surface, an antenna pattern formed on at least one of the first main surface and the second main surface, and an antenna pad extending from the antenna pattern and formed on the side surface. The antenna device is welded onto a printed circuit motherboard at the antenna pad.

### CROSS-REFERENCE TO RELATED APPLICATION

This application claims the benefit of the filing date under 35 U.S.C. § 119(a)-(d) of Chinese Patent Application No. 202410214247.7, filed on Feb. 27, 2024.

### FIELD OF THE INVENTION

Embodiments of the present disclosure generally relate to an antenna device and an antenna device assembly, and more particularly to an antenna device and an antenna device assembly adapted for automated assembly.

### BACKGROUND OF THE INVENTION

In existing mounting technology of an antenna device, the antenna device is usually manually mounted onto a circuit motherboard. In one example, for antennas made of material such as a stamped metal and a printed circuit board assembly (PCBA) commonly used in the current market, they are usually manually inserted and mounted onto the printed circuit motherboard in a vertical mounting mode. In another example, for a chip antenna, a coaxial cable flexible printed circuit (FPC), and a printed circuit board (PCB) antenna commonly used in the current market, the chip antenna is usually mounted onto the printed circuit motherboard in a horizontal mounting mode by surface mounting technology. The FPC antennas and the PCB antennas are usually manually assembled to a plastic housing of a device using double-sided tape on the production line, and the FPC antennas and PCB antennas may be mounted in the horizontal mounting mode or in the vertical mounting mode depending on the actual situation.

However, the abovementioned existing antennas are only suitable for manual assembly techniques on the production line and cannot meet the requirements for automated assembly on the production line. In addition, some types of existing antennas cannot meet the requirements of selective assembly for realizing the dual modes (placed horizontally/vertically) due to their own structure.

### SUMMARY OF THE INVENTION

An antenna device includes a substrate having a first main surface, a second main surface opposite the first main surface, and a side surface connecting the first main surface and the second main surface, an antenna pattern formed on at least one of the first main surface and the second main surface, and an antenna pad extending from the antenna pattern and formed on the side surface. The antenna device is welded onto a printed circuit motherboard at the antenna pad.

### BRIEF DESCRIPTION OF THE DRAWINGS

Features of the present invention will become more apparent by describing in detail exemplary embodiments thereof with reference to the accompanying drawings, in which:

FIG. 1 is a schematic structural view of an antenna device according to an exemplary embodiment of the present disclosure, mainly showing a configuration of a first main surface and a side surface of the antenna device;

FIG. 2 is another schematic structural view of the antenna device according to the exemplary embodiment of the present disclosure, mainly showing a configuration of a second main surface of the antenna device;

FIG. 3 shows a schematic structural view of the antenna device assembled onto a printed circuit motherboard in a horizontal mounting mode according to the exemplary embodiment of the present disclosure;

FIG. 4 shows a schematic structural view of the antenna device assembled onto a printed circuit motherboard in a vertical mounting mode according to the exemplary embodiment of the present disclosure;

FIG. 5 shows a schematic view of a state of an antenna device assembly according to the exemplary embodiment of the present disclosure, before being assembled onto the printed circuit motherboard; and

FIG. 6 shows a schematic view of a state of the antenna device assembly according to the exemplary embodiment of the present disclosure, after being assembled to the printed circuit motherboard.

### DETAILED DESCRIPTION

Embodiments of the present disclosure will be described hereinafter in detail taken in conjunction with the accompanying drawings. In the description, the same or similar parts are indicated by the same or similar reference numerals. The description of each of the embodiments of the present disclosure hereinafter with reference to the accompanying drawings is intended to explain the general inventive concept of the present disclosure and should not be construed as a limitation on the present disclosure.

In addition, in the following detailed description, for the sake of explanation, numerous specific details are set forth in order to provide a thorough understanding of the disclosed embodiments. It will be apparent, however, that one or more embodiments may also be practiced without these specific details. In other instances, well-known structures and devices are illustrated schematically in order to simplify the drawing.

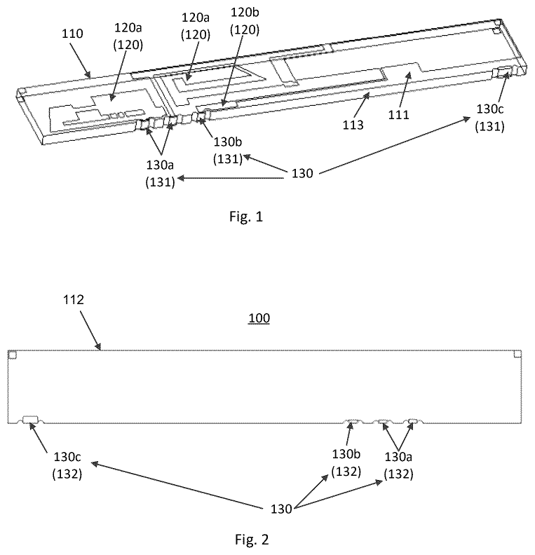

Referring to FIGS. 1 and 2, according to an exemplary embodiment of the present disclosure, there is provided an antenna device 100. The antenna device 100 includes a substrate 110, an antenna pattern 120 formed on the substrate 110, and an antenna pad 130.

According to the exemplary embodiment of the present disclosure, the substrate 110 is generally flat and has a first main surface 111, a second main surface 112 opposed to the first main surface 111, and at least one side surface 113 connecting the first main surface 111 and the second main surface 112. The antenna pattern 120 is formed on at least one of the first main surface 111 and the second main surface 112. In the illustrated embodiment, the antenna pattern 120 is only formed on the first main surface 111. However, in other embodiments according to the inventive concept of the present disclosure, the antenna pattern 120 may also be formed on the second main surface 112, or formed on both the first main surface 111 and the second main surface 112. According to the present disclosure, taking the illustrated embodiment as an example, the antenna pattern 120 may be a printed circuit formed on the first main surface 111 of the substrate 110, and including but not limited to, for example, a signal circuit and a ground circuit. The antenna pad 130 extends from the antenna pattern 120 and is formed at least on the side surface 113, for welding the antenna device 100 onto a printed circuit motherboard 300 through the antenna pad 130.

According to the embodiment of the present disclosure, as shown in FIGS. 1 and 2, the antenna pad 130 further includes a first pad portion 131 and a second pad portion 132. In the embodiment shown in FIG. 1, the first pad portion 131 is formed on the side surface 113, for welding the antenna device 100 onto the printed circuit motherboard 300 in a vertical mounting mode in which the antenna device 100 is placed vertically relative to the printed circuit motherboard 300. As shown in FIG. 2, the second pad portion 132 is formed on the second main surface 112, for welding the antenna device 100 onto the printed circuit motherboard 300 in a horizontal mounting mode in which the antenna device 100 is placed horizontally relative to the printed circuit motherboard 300. According to the inventive concept of the present disclosure, in other embodiments not shown, the second pad portion 132 is also formed on the first main surface 111 having the antenna pattern 120.

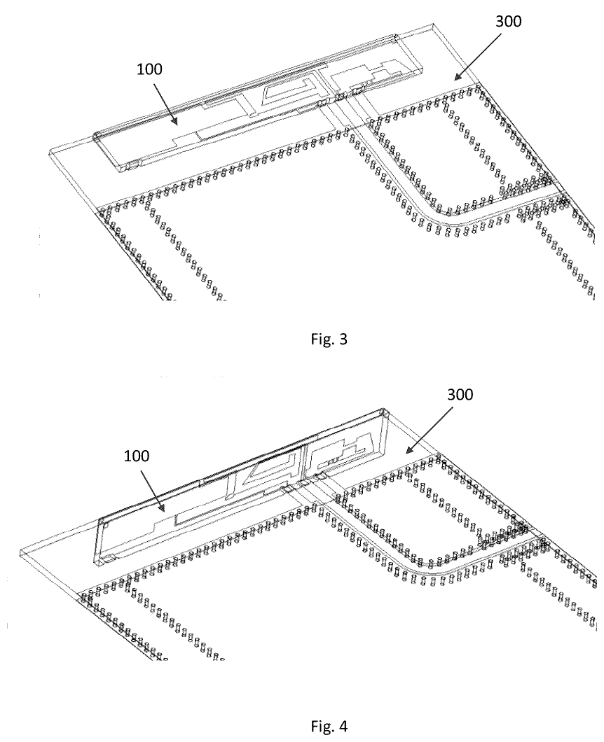

Herein, the “horizontal mounting mode” refers to a state where a plane in which the antenna pattern 120 of the antenna device 100 is located is parallel to a mounting surface of the printed circuit motherboard 300 (as shown in FIG. 3), and the “vertical mounting mode” refers to a state where the plane in which the antenna pattern 120 of the antenna device 100 is located is perpendicular to the mounting surface of the printed circuit motherboard 300 (as shown in FIG. 4). That is to say, in the horizontal mounting mode, various types of circuits in the antenna pattern 120 of the antenna device 100 can be connected to the corresponding circuits on the printed circuit motherboard 300 through the second pad portion 132 formed on the second main surface 112. In the vertical mounting mode, various types of circuits in the antenna pattern 120 of the antenna device 100 can be connected to corresponding circuits on the printed circuit motherboard 300 through the first pad portion 131 formed on the side surface 113. In addition, by adopting the first pad portion 131 formed on both the side surface 113 and the second main surface 112 and the second pad portion 132 formed on the second main surface 112, respectively, the antenna device 100 is adapted to be assembled onto the printed circuit motherboard 300 by the surface mounting technology.

According to one embodiment of the present disclosure, the first pad portion 131 extends from the antenna pattern 120, and the second pad portion 132 extends from the first pad portion 131. According to another embodiment of the present disclosure, the first pad portion 131 and the second pad portion 132 may also extend from the antenna pattern 120, respectively. In addition, grooves are provided on both sides of the first pad portion 131, as shown in FIGS. 1 and 2.

With the abovementioned configuration, according to the present disclosure, there is provided an antenna device 100 capable of selectively realizing a horizontal mounting mode or a vertical mounting mode on the production line, which provides flexibility for the use of the antenna device 100.

As shown in FIG. 1, in the antenna device 100 according to the embodiments of the present disclosure, the antenna pattern 120 further includes at least one signal pattern 120a and at least one ground pattern 120b separated from each other, and the antenna pad 130 further includes at least one signal pad 130a and at least one ground pad 130b separated from each other. The at least one signal pad 130a extends from the at least one signal pattern 120a, and the at least one ground pad 130b extends from the at least one ground pattern 120b.

In the exemplary embodiment shown in FIG. 1, the antenna pattern 120 includes a pair of signal patterns 120a and a ground pattern 120b. For example, as shown in FIGS. 1 and 2, one signal pad 130a (i.e., the first pad portion 131) located on the side surface 113 and one signal pad 130a (i.e., the second pad portion 132) located on the second main surface 112 extend from each of the pair of signal patterns 120a, and one ground pad 130b (i.e., the first pad portion 131) located on the side surface 113 and one ground pad 130b (i.e., the second pad portion 132) located on the second main surface 112 extend from the ground pattern 120b. In other embodiments, the number, position, and/or layout of the signal pattern(s) 120a, the ground pattern(s) 120b, the signal pad(s) 130a, and the ground pad(s) 130b are not limited to those shown.

In addition, the antenna pattern 120 further includes at least one fixing pad 130c, shown in FIGS. 1 and 2. The fixing pad 130c is formed at least on the side surface 113 (and the second main surface 112) for fixing the antenna device 100 onto the printed circuit motherboard 300. In the exemplary embodiment shown in FIGS. 1 and 2, there is one fixing pad 130c located on the side surface 113 and one fixing pad 130c located on the second main surface 112. Of course, in other embodiments, the number, position, and/or layout of the fixing pad(s) 130c is not limited to the shown embodiment.

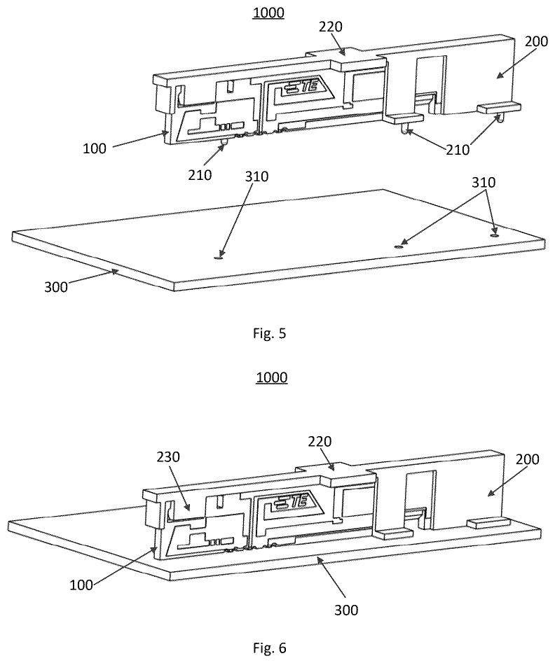

Referring to FIGS. 5 to 6, according to the exemplary embodiment of the present disclosure, there is also provided an antenna device assembly 1000. The antenna device assembly 1000 includes an antenna device 100 according to any one of the aforementioned embodiments and a bracket 200. The bracket 200 is attached to the antenna device 100, for carrying the antenna device 100 to automatically assemble the antenna device 100 onto the printed circuit motherboard 300 in the vertical mounting mode in which the antenna device 100 is placed vertically relative to the printed circuit motherboard 300.

As shown in the embodiment of FIGS. 5 and 6, the bracket 200 includes at least one positioning pin 210. The positioning pin 210 is used for engaging a positioning hole 310 formed in the printed circuit motherboard 300 to position the bracket 200 and the antenna device 100 onto the printed circuit motherboard 300. For example, in the exemplary embodiments shown in FIGS. 5 to 6, legs are formed on two sides of a bottom of the bracket 200, respectively, and each leg is formed with the aforementioned positioning pin 210. With the provision of the legs and the positioning pins 210 at the bottom of the bracket 200, it is ensured that the antenna device 100 does not roll over or be mispositioned when being assembled onto the printed circuit motherboard 300 in the vertical mounting mode.

According to the embodiments of the present disclosure, as shown in FIGS. 5 and 6, the bracket 200 includes a picking platform 220. As shown in FIGS. 5 and 6, the picking platform 220 is formed at a top of the bracket 200, and has a picking area of at least about 5 mm×5 mm to facilitate a picking action of a picking nozzle on the production line. The picking platform 220 may be made of temperature resistant material capable of withstanding at least about 260 degrees Celsius.

According to the embodiments of the present disclosure, the bracket 200 is detachably or integrally attached to the antenna device 100. In the exemplary embodiments shown in FIGS. 5 to 6, the bracket 200 is detachably attached to the antenna device 100 through a hook structure 230. In other embodiments not shown, the bracket 200 may also be detachably attached to the antenna device 100 through other suitable detachable structures.

The antenna device and the antenna device assembly according to the foregoing exemplary embodiments of the present disclosure can selectively realize the automatic surface mounting technology of the antenna device in a horizontal mounting mode or a vertical mounting mode on the production line, which provides flexibility for the use of the antenna device, optimizes performance of the antenna device, and saves the cost of automated assembly on the production line. Furthermore, in a case where the antenna device is arranged in the vertical mounting mode according to the present disclosure, the layout of the pads on the main surface of the printed circuit motherboard may be reduced because the pads are formed on the side surface, and the vertical mounting mode of the antenna device is more favorable to achieve manufacturing automation.

It should be appreciated by those skilled in the art that the above embodiments are intended to be illustrative, and many modifications may be made to the above embodiments by those skilled in the art. Further, various structures described in various embodiments may be freely combined with each other without conflicting in configuration or principle.

Although the present disclosure has been described hereinbefore in detail with reference to the accompanying drawings, it should be appreciated that the disclosed embodiments in the accompanying drawings are intended to illustrate embodiments of the present disclosure by way of example, and should not be construed as a limitation to the present disclosure.

Although some embodiments of the general inventive concept of the present disclosure have been shown and described, it would be appreciated by those skilled in the art that changes or modification may be made to these embodiments without departing from the principles and spirit of the general inventive concept, the scope of which is defined in claims and their equivalents.

It should be noted that, the word “comprise” or “include” doesn't exclude other elements or steps, and the word “a” or “an” doesn't exclude more than a plurality. In addition, any reference numerals in the claims should not be interpreted as the limitation to the scope of the present disclosure.

1. An antenna device, comprising:
a substrate having a first main surface, a second main surface opposite the first main surface, and a side surface connecting the first main surface and the second main surface;
an antenna pattern formed on at least one of the first main surface and the second main surface; and
an antenna pad extending from the antenna pattern and formed on the side surface, the antenna device welded onto a printed circuit motherboard at the antenna pad.

2. The antenna device according to claim 1, wherein the antenna pad includes a first pad portion formed on the side surface, the antenna device is welded onto the printed circuit motherboard at the first pad portion in a vertical mounting mode in which the antenna device is placed vertically relative to the printed circuit motherboard.

3. The antenna device according to claim 2, wherein the antenna pad includes a second pad portion formed on the first main surface or the second main surface, the antenna device is welded onto the printed circuit motherboard at the second pad portion in a horizontal mounting mode in which the antenna device is placed horizontally relative to the printed circuit motherboard.

4. The antenna device according to claim 3, wherein the first pad portion extends from the antenna pattern.

5. The antenna device according to claim 4, wherein the second pad portion extends from the first pad portion or the antenna pattern.

6. The antenna device according to claim 5, wherein a plurality of grooves are provided in the substrate, the grooves are disposed on a pair of opposite sides of the first pad portion.

7. The antenna device according to claim 1, wherein the antenna pattern includes a signal pattern and a ground pattern separated from each other.

8. The antenna device according to claim 7, wherein the antenna pad has a signal pad and a ground pad separated from each other.

9. The antenna device according to claim 8, wherein the signal pad extends from the signal pattern and the ground pad extends from the ground pattern.

10. The antenna device according to claim 1, further comprising a fixing pad formed on the side surface and fixing the antenna device onto the printed circuit motherboard.

11. The antenna device according to claim 1, wherein the antenna device is assembled onto the printed circuit motherboard by a surface mounting technology.

12. An antenna device assembly, comprising:
an antenna device including a substrate having a first main surface, a second main surface opposite the first main surface, and a side surface connecting the first main surface and the second main surface, an antenna pattern formed on at least one of the first main surface and the second main surface, and an antenna pad extending from the antenna pattern and formed on the side surface, the antenna device is welded onto a printed circuit motherboard at the antenna pad; and
a bracket attached to the antenna device and assembling the antenna device onto the printed circuit motherboard in a vertical mounting mode in which the antenna device is placed vertically relative to the printed circuit motherboard.

13. The antenna device assembly according to claim 12, wherein the bracket includes a positioning pin engaging a positioning hole in the printed circuit motherboard to position the bracket and the antenna device on the printed circuit motherboard.

14. The antenna device assembly according to claim 12, wherein the bracket has a picking platform with a picking area of at least 5 mm×5 mm.

15. The antenna device assembly according to claim 14, wherein the picking platform is made of temperature resistant material capable of withstanding at least 260 degrees Celsius.

16. The antenna device assembly according to claim 12. wherein the bracket is detachably or integrally attached to the antenna device.
